(19) United States
(12) Patent Application Publication
(10) Pub. No.: US 2003/0076144 A1
(43) Pub. Date: Apr. 24, 2003

(54) Schmitt trigger circuit consuming low power

(76) Inventor: Shinichi Hirose, Hyogo (JP)

Correspondence Address: Platon N. Mandros, Burns, Doane, Swecker & Mathis, L.L.P., P.O. Box 1404, Alexandria, VA, 22313-1404, US

(21) Appl. No.: 10/098,500

(22) Filed: Mar. 18, 2002

(30) Foreign Application Priority Data
Oct. 22, 2001 (JP) 2001-323205(P)

(51) Int. Cl. H03K 3/037

(52) U.S. Cl. 327/206

(57) ABSTRACT

A Schmitt trigger circuit includes: an NAND gate receiving a control signal and an input signal; an inverter outputting an inverted signal of an output signal of the NAND gate; first and second P channel MOS transistors and first and second N channel MOS transistors switching a threshold potential of the Schmitt trigger circuit in response to an output signal of the inverter; and a third N channel MOS transistor receiving the control signal at a gate thereof. When the control signal attains L level, the third N channel MOS transistor is rendered non-conductive. Therefore, a through current does not flow through the first-third N channel MOS transistors. Thus, Schmitt width can be freely designed and power consumption will be small.

### BACKGROUND OF THE INVENTION

1. Field of the Invention

The present invention relates to a Schmitt trigger circuit, and more particularly to a Schmitt trigger circuit having two threshold potentials different from each other.

2. Description of the Background Art

FIG. 10 is a circuit diagram showing a configuration of a conventional Schmitt trigger circuit. In FIG. 10, the Schmitt trigger circuit includes an NAND gate 31, an inverter 32, P channel MOS transistors 33, 34 and N channel MOS transistors 35, 36. MOS transistors 33-36 are serially connected between lines of power supply potential VCC and ground potential GND. A control signal CNT is input to one input node of NAND gate 31, and an input signal VI is input to the other input node thereof and to gates of MOS transistors 34, 35. An output signal VM of NAND gate 31 is provided to a node N34 between MOS transistors 34, 35, and is input to gates of MOS transistors 33, 36 via inverter 32. An output signal of inverter 32 is provided as an output signal VO of the Schmitt trigger circuit.

An operation of the Schmitt trigger circuit shown in FIG. 10 will now be described. When control signal CNT is at H (high) level, NAND gate 31 operates as an inverter for input signal VI. At a certain time point, signal VI is assumed to be set at H level. Here, output signal VM of NAND gate 31 attains L (low) level, output signal VO of inverter 32 attains H level, P channel MOS transistors 33, 34 are rendered non-conductive, and N channel MOS transistors 35, 36 are conductive.

When a level of signal VI lowers from H level to L level, correspondingly, resistance value of P channel MOS transistor 34 decreases, resistance value of N channel MOS transistor 35 increases, and a level of signal VM is raised from L level to H level. When the level of signal VM exceeds a threshold potential of inverter 32, signal VO will fall from H level to L level. In addition, P channel MOS transistors 33, 34 are rendered conductive, N channel MOS transistors 35, 36 are rendered non-conductive, and signal VM is held at H level.

When the level of signal VI is raised from L level to H level, correspondingly, resistance value of P channel MOS transistor 34 increases, resistance value of N channel MOS transistor 35 decreases, and the level of signal VM lowers from H level to L level. When the level of signal VM exceeds the threshold potential of inverter 32, signal VO will rise from L level to H level. In addition, P channel MOS transistors 33, 34 are rendered non-conductive, N channel MOS transistors 35, 36 are rendered conductive, and signal VM is held at L level.

When control signal CNT then falls from H level to L level, output signal VM of NAND gate 31 attains H level and output signal VO attains L level. In addition, P channel MOS transistor 33 is rendered conductive, N channel MOS transistor 36 is rendered non-conductive, and signal VM is held at H level.

In the conventional Schmitt trigger circuit, however, if control signal CNT falls from H level to L level when signals CNT and VI are both at H level, a through current will flow from an output node of NAND gate 31 through N channel MOS transistors 35, 36 to a line of ground potential GND. Accordingly, current driving power of NAND gate 31 had to be made sufficiently larger than that of N channel MOS transistors 35, 36, and Schmitt width could not be designed freely. Moreover, due to the flow of the through current, the Schmitt trigger circuit consumes a large amount of current.

### SUMMARY OF THE INVENTION

Therefore, an object of the present invention is to provide a Schmitt trigger circuit of which Schmitt width can be designed freely and power consumption is small.

A Schmitt trigger circuit according to the present invention includes: a logic circuit outputting an inverted signal of an input signal of the Schmitt trigger circuit to a prescribed node in response to a control signal having attained an active level, and providing a first potential to the prescribed node in response to the control signal having attained an inactive level; an inverting circuit outputting an inverted signal of a signal appearing at the prescribed node, as an output signal of the Schmitt trigger circuit; a first transistor of a first conductivity type and a second transistor of a second conductivity type, receiving an input signal of the Schmitt trigger circuit at respective input electrodes; a switching element rendered non-conductive in response to the control signal having attained an inactive level; and a switching circuit switching between the first and second threshold potentials by connecting the first transistor between a line of the first potential and the prescribed node in response to an output signal of the inverting circuit set to a second potential and by serially connecting the second transistor and the switching element between a line of the second potential and the prescribed node in response to the output signal of the inverting circuit set to the first potential. Therefore, since the switching element is rendered non-conductive in response to the control signal having attained the inactive level, continuous current flow from the prescribed node through the second transistor to the line of the second potential can be prevented, and power consumption will be small. In addition, as ratio of current driving power of the logic circuit to that of the second transistor can be freely designed, Schmitt width can be freely designed.

Preferably, the switching element includes a third transistor of the second conductivity type. A fourth transistor of the first conductivity type, receiving the second potential at an input electrode thereof, is further provided. The switching circuit serially connects the first and fourth transistors between the line of the first potential and the prescribed node in response to an output signal of the inverting circuit set to the second potential. In this case, symmetry of the circuit can be improved.

Preferably, the logic circuit includes: fifth and sixth transistors of the first conductivity type, connected in parallel between the line of the first potential and the prescribed node, and receiving the control signal and the input signal at respective input electrodes; and seventh and eighth transistors of the second conductivity type serially connected between the line of the second potential and the prescribed node, one of the transistors receiving the control signal at an input electrode thereof and the other one of the transistors receiving the input signal at an input electrode thereof. In this case, the logic circuit can be easily formed.

Preferably, the logic circuit further includes a ninth transistor of the first conductivity type, serially connected to each of the fifth and sixth transistors between the line of the first potential and the prescribed node, and receiving the second potential at an input electrode thereof. In this case, symmetry of the circuit can be improved.

In addition, another Schmitt trigger circuit according to the present invention includes: a first logic circuit outputting an inverted signal of an input signal of the Schmitt trigger circuit to a prescribed node in response to a control signal having attained an active level, and providing a first potential to the prescribed node in response to the control signal having attained an inactive level; a second logic circuit outputting an inverted signal of a signal appearing at the prescribed node, as an output signal of the Schmitt trigger circuit in response to the control signal having attained an active level; a first transistor of a first conductivity type and a second transistor of a second conductivity type, receiving an input signal of the Schmitt trigger circuit at input electrodes thereof; and a switching circuit switching between the first and second threshold potentials by connecting the first transistor between a line of the first potential and the prescribed node in response to an output signal of the second logic circuit set to the second potential and by connecting the second transistor between a line of the second potential and the prescribed node in response to an output signal of the second logic circuit set to the first potential. Therefore, since the second transistor is disconnected from the line of the second potential and the prescribed node in response to the control signal having attained the inactive level, continuous flow of a through current from the prescribed node through the second transistor to the line of the second potential can be prevented, and power consumption will be small. In addition, as ratio of current driving power of the logic circuit to that of the second transistor can be freely designed, Schmitt width can be freely designed.

Preferably, the first logic circuit includes: third and fourth transistors of the first conductivity type, connected in parallel between the line of the first potential and the prescribed node, and receiving the control signal and the input signal at respective input electrodes; and fifth and sixth transistors of the second conductivity type serially connected between the line of the second potential and the prescribed node, one of the transistors receiving the control signal at an input electrode thereof, and the other of the transistors receiving the input signal at an input electrode thereof. In this case, the first logic circuit can be easily formed.

Preferably, the first logic circuit further includes a seventh transistor of the first conductivity type, serially connected to each of the fifth and sixth transistors between the line of the first potential and the prescribed node, and receiving the second potential at an input electrode thereof. In this case, symmetry of the circuit can be improved.

Preferably, the second logic circuit includes: ninth and tenth transistors of the first conductivity type serially connected between a line of the first potential and an output node, one of the transistors receiving an inverted signal of the control circuit at an input electrode thereof and the other one of the transistors receiving a signal appearing at the prescribed node at an input electrode thereof; and eleventh and twelfth transistors of the second conductivity type, connected in parallel between the line of the second potential and the output node, and receiving an inverted signal of the control signal and the signal appearing at the prescribed node respectively at input electrodes thereof. In this case, the second logic circuit can be easily formed.

Preferably, the second logic circuit further includes a thirteenth transistor of the second conductivity type, serially connected to each of the eleventh and twelfth transistors between the line of the second potential and the output node, and receiving the first potential at an input electrode thereof. In this case, symmetry of the circuit can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a configuration of a Schmitt trigger circuit according to a first embodiment of the present invention.

FIG. 2 is a circuit diagram showing a configuration of an NAND gate shown in FIG. 1.

FIG. 3 is a circuit diagram showing a variation of the first embodiment.

FIG. 4 is a circuit diagram showing another variation of the first embodiment.

FIG. 5 is a circuit diagram showing a yet another variation of the first embodiment.

FIG. 6 is a circuit diagram showing a configuration of a Schmitt trigger circuit according to a second embodiment of the present invention.

FIG. 7 is a circuit diagram showing a configuration of an NOR gate shown in FIG. 6.

FIG. 8 is a circuit diagram showing a variation of the second embodiment.

FIG. 9 is a circuit diagram showing another variation of the second embodiment.

FIG. 10 is a circuit diagram showing a configuration of a conventional Schmitt trigger circuit.

### DESCRIPTION OF THE PREFERRED EMBODIMENTS

(First Embodiment)

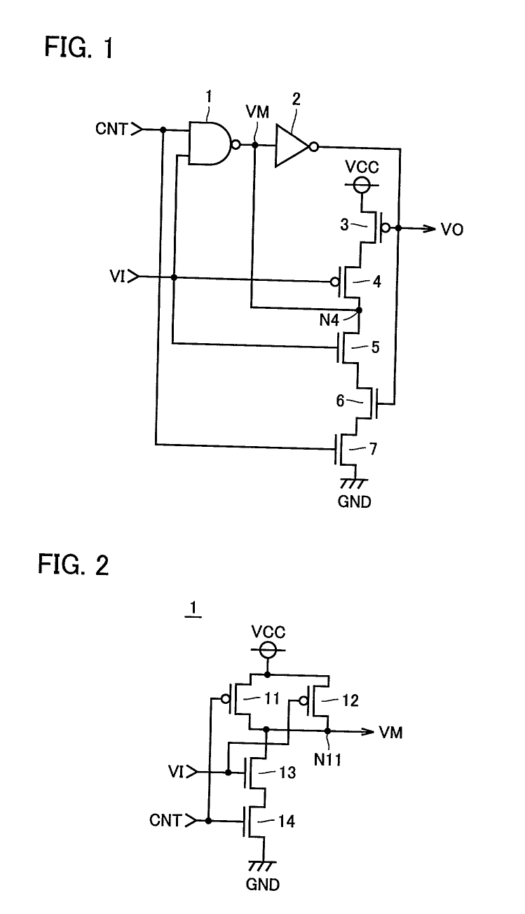

FIG. 1 is a circuit diagram showing a configuration of a Schmitt trigger circuit according to a first embodiment of the present invention. In FIG. 1, the Schmitt trigger circuit includes an NAND gate 1, an inverter 2, P channel MOS transistors 3, 4 and N channel MOS transistors 5-7. MOS transistors 3-7 are serially connected between lines of power supply potential VCC and ground potential GND. A control signal CNT is input to one input node of NAND gate 1 and to a gate of N channel MOS transistor 7. An input signal VI is input to the other input node of NAND gate 1 and to gates of MOS transistors 4, 5. An output signal VM of NAND gate 1 is input to inverter 2 and to a node N4 between MOS transistors 4, 5. An output signal of inverter 2 is input to gates of MOS transistors 3, 6. The output signal of inverter 2 becomes an output signal VO of the Schmitt trigger circuit.

FIG. 2 is a circuit diagram showing a configuration of NAND gate 1 shown in FIG. 1. In FIG. 2, NAND gate 1 includes P channel MOS transistors 11, 12 and N channel MOS transistors 13, 14. P channel MOS transistors 11, 12 are connected in parallel between a line of power supply potential VCC and an output node N11, and N channel MOS transistors 13, 14 are serially connected between output node N11 and a line of ground potential GND. Control signal CNT is provided to gates of MOS transistors 11, 14, and input signal VI is provided to gates of MOS transistors 12, 13.

When signals CNT and VI are both at H level, P channel MOS transistors 11, 12 are rendered non-conductive, N channel MOS transistors 13, 14 are rendered conductive, and output signal VM attains L level. When signals CNT and VI are at H level and L level respectively, MOS transistors 11, 13 are rendered non-conductive, MOS transistors 12, 14 are rendered conductive, and output signal VM attains H level. When signals CNT and VI are at L level and H level respectively, MOS transistors 12, 14 are rendered non-conductive, MOS transistors 11, 13 are rendered conductive, and output signal VM attains H level. When signals CNT and VI are both at L level, P channel MOS transistors 11, 12 are rendered conductive, N channel MOS transistors 13, 14 are rendered non-conductive, and output signal VM attains H level. In other words, only when signals CNT and VI are both at H level, signal VM attains L level, and when at least one of signals CNT and VI is at L level, signal VM attains H level.

An operation of the Schmitt trigger circuit shown in FIGS. 1 and 2 will now be described. When control signal CNT is at H level, P channel MOS transistor 11 of NAND gate 1 is rendered non-conductive, N channel MOS transistor 14 is rendered conductive, and NAND gate 1 operates as an inverter for input signal VI. Here, N channel MOS transistor 7 is conductive.

At a certain time point, signal VI is assumed to be set at H level. Here, output signal VM of NAND gate 1 attains L level, output signal VO of inverter 2 attains H level, P channel MOS transistors 3, 4 are rendered non-conductive, and N channel MOS transistors 5-7 are conductive.

When a level of signal VI then lowers from H level to L level, correspondingly, resistance value of P channel MOS transistors 4, 12 decreases and resistance value of N channel MOS transistors 5, 13 increases. When a level of a current flowing from a line of power supply potential VCC through P channel MOS transistor 12 into node N4 (N11) exceeds that of a current flowing from node N4 (N11) through N channel MOS transistors 13, 14 and N channel MOS transistors 5-7 out to a line of ground potential GND, a level of node N4 (N11) rises from L level to H level, and a level of output signal VO of inverter 2 falls from H level to L level. In addition, P channel MOS transistor 3 is rendered conductive, N channel MOS transistor 6 is rendered non-conductive, and node N4 (N11) is held at L level.

Here, in order for the level of output signal VO to fall from H level to L level, the level of the current flowing in P channel MOS transistor 12 has to exceed that of the current flowing in N channel MOS transistors 13, 14 and N channel MOS transistors 5-7. Therefore, a level VIL (a first threshold potential) of input signal VI at that time is sufficiently lower than power supply potential VCC. Thus, even if input signal VI at H level includes noise component to some extent, the level of output signal VO will not change.

When the level of signal VI is then raised from L level to H level, correspondingly, resistance value of N channel MOS transistors 5, 13 decreases and resistance value of P channel MOS transistors 4, 12 increases. When the level of the current flowing from node N4 (N11) through N channel MOS transistors 13, 14 out to a line of ground potential GND exceeds that of the current flowing from the line of power supply potential VCC through P channel MOS transistor 12 and P channel MOS transistors 3, 4 into node N4 (N11), the level of node N4 (N11) falls from H level to L level, and output signal VO of inverter 2 rises from L level to H level. In addition, P channel MOS transistor 3 is rendered non-conductive, N channel MOS transistor 6 is rendered conductive, and node N4 (N11) is held at L level.

Here, in order for the level of output signal VO to rise from L level to H level, the level of the current flowing in N channel MOS transistors 13, 14 has to exceed that of the current flowing in P channel MOS transistor 12 and P channel MOS transistors 3, 4. Therefore, a level VIH (a second threshold potential) of input signal VI at that time is sufficiently higher than ground potential GND. Thus, even if input signal VI at L level includes noise component to some extent, the level of output signal VO will not change.

Next, control signal CNT falls from H level to L level, P channel MOS transistor 11 is rendered conductive, N channel MOS transistors 7, 14 are rendered non-conductive, and node N4 (N11) is charged to H level. Here, since N channel MOS transistor 7 is non-conductive, a through current does not flow from the line of power supply potential VCC to the line of ground potential GND. When node N4 (N11) attains H level, output signal VO falls from H level to L level, P channel MOS transistor 3 is rendered conductive, N channel MOS transistor 6 is rendered non-conductive, and node N4 (N11) is held at H level.

The Schmitt trigger circuit has a property that the level VIL of input signal VI when the level of output signal VO changes from H level to L level is sufficiently lower than power supply potential VCC, and the level VIH of input signal VI when the level of output signal VO changes from L level to H level is sufficiently higher than ground potential GND. Therefore, even if input signal VI includes noise component to some extent, the level of output signal VO will not change. Accordingly, the Schmitt trigger circuit is used as an input circuit, for example, of a semiconductor integrated circuit device. Control signal CNT is set at L level when an input circuit is not necessary.

In the first embodiment, since N channel MOS transistor 7, which is rendered non-conductive in response to control signal CNT having attained L level, is interposed between a source of N channel MOS transistor 6 and the line of ground potential GND, a through current does not flow from the line of power supply potential VCC to the line of ground potential GND even when control signal CNT falls from H level to L level. Therefore, ratio of current driving power of NAND gate 1 to that of N channel MOS transistors 5-7 as well as Schmitt width VIH-VIL can be freely designed. In addition, as the through current does not flow, power consumption will be small.

Obviously, the same effect will be obtained even if positions of P channel MOS transistors 3 and 4 or positions of N channel MOS transistors 5-7 are switched.

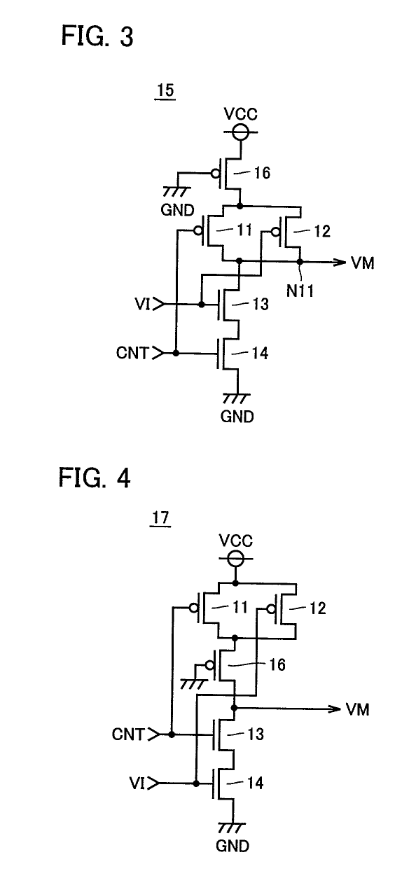

In the following, several variations will be described. In a variation in FIG. 3, NAND gate 1 is replaced with an NAND gate 15. NAND gate 15 is different from NAND gate 1 in FIG. 2 in that a P channel MOS transistor 16 is added. P channel MOS transistor 16 is interposed between the line of power supply potential VCC and sources of P channel MOS transistors 11, 12, and receives ground potential GND at a gate thereof. P channel MOS transistor 16 constitutes a resistive element. In this variation, two P channel MOS transistors 12, 16 and two N channel MOS transistors 13, 14 constitute an inverter when control signal CNT is at H level. Thus, symmetry of a circuit can be easily obtained.

In a variation in FIG. 4, NAND gate 1 is replaced with an NAND gate 17. In NAND gate 17, positions of P channel MOS transistor 16 and P channel MOS transistors 11, 12 in NAND gate 15 in FIG. 3 are switched. In addition, control signal CNT is provided to gates of MOS transistors 11, 13, and input signal VI is provided to gates of MOS transistors 12, 14. Here also, the same effect as in the variation in FIG. 3 will be obtained.

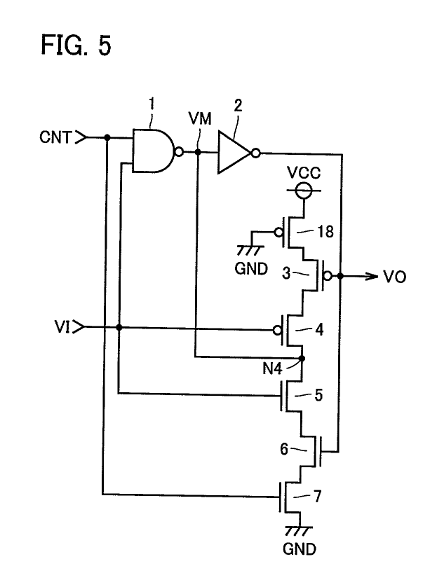

In a variation in FIG. 5, a P channel MOS transistor 18 is added. P channel MOS transistor 18 is interposed between the line of power supply potential VCC and a source of P channel MOS transistor 3, and receives ground potential GND at a gate thereof. P channel MOS transistor 18 constitutes a resistive element. In this variation, three P channel MOS transistors 3, 4, 18 and three N channel MOS transistors 5-7 constitute an inverter when control signal CNT is at H level. Thus, symmetry of a circuit can be easily obtained.

(Second Embodiment)

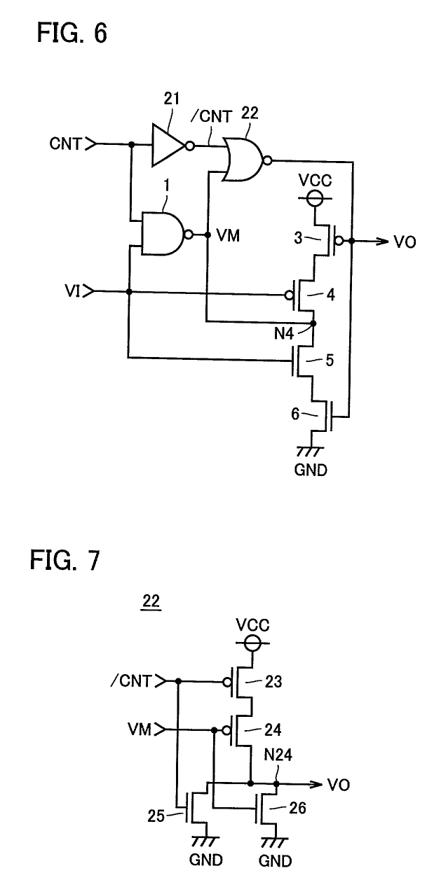

FIG. 6 is a circuit diagram showing a configuration of a Schmitt trigger circuit according to a second embodiment of the present invention. The Schmitt trigger circuit in FIG. 6 is different from the one in FIG. 1 in that an inverter 21 and an NOR gate 22 are added and inverter 2 and N channel MOS transistor 7 are removed. MOS transistors 3-6 are serially connected between lines of power supply potential VCC and ground potential GND. Control signal CNT is input to one input node of NAND gate 1 and to one input node of NOR gate 22 via inverter 21. Input signal VI is input to the other input node of NAND gate 1 and to gates of MOS transistors 4, 5. Output signal VM of NAND gate 1 is input to the other input node of NOR gate 22 and to node N4 between MOS transistors 4, 5. An output signal of NOR gate 22 is input to gates of MOS transistors 3, 6. Output signal of NOR gate 22 becomes an output signal VO of the Schmitt trigger circuit.

FIG. 7 is a circuit diagram showing a configuration of NOR gate 22 shown in FIG. 6. In FIG. 7, NOR gate 22 includes P channel MOS transistors 23, 24 and N channel MOS transistors 25, 26. P channel MOS transistors 23, 24 are serially connected between the line of power supply potential VCC and an output node N24, and N channel MOS transistors 25, 26 are connected in parallel between output node N24 and the line of ground potential GND. An inverted signal /CNT of control signal CNT is input to gates of MOS transistors 23, 25, and output signal VM of NAND gate 1 is input to gates of MOS transistors 24, 26.

When signals /CNT and VM are both at L level, P channel MOS transistors 23, 24 are rendered conductive, N channel MOS transistors 25, 26 are rendered non-conductive, and signal VO attains H level. When signals /CNT and VM are at L level and H level respectively, MOS transistors 23, 26 are rendered conductive, MOS transistors 24, 25 are rendered non-conductive, and signal VO attains L level. When signals /CNT and VM are at H level and L level respectively, MOS transistors 24, 25 are rendered conductive, MOS transistors 23, 26 are rendered non-conductive, and signal VO attains L level. When signals /CNT and VM are both at H level, N channel MOS transistors 25, 26 are rendered conductive, P channel MOS transistors 23, 24 are rendered non-conductive, and signal VO attains L level. In other words, only when signals /CNT and VM are both at L level, signal VO attains H level, and when at least one of signals /CNT and VM is at H level, signal VO attains L level.

An operation of the Schmitt trigger circuit shown in FIGS. 6 and 7 will now be described. When control signal CNT is at H level, signal /CNT attains L level, P channel MOS transistor 23 is rendered conductive, N channel MOS transistor 25 is rendered non-conductive, and NOR gate 22 operates as an inverter for output signal VM of NAND gate 1.

At a certain time point, signal VI is assumed to be set at H level. Here, output signal VM of NAND gate 1 attains L level, output signal VO of NOR gate 22 attains H level, P channel MOS transistors 3, 4 are rendered non-conductive, and N channel MOS transistors 5, 6 are conductive.

When a level of signal VI then lowers from H level to L level, correspondingly, resistance value of P channel MOS transistors 4, 12 decreases, resistance value of N channel MOS transistors 5, 13 increases, and the level of node N4 (N11) is raised from L level to H level. When the level of node N4 (N11) exceeds the threshold potential of NOR gate 22, a level of signal VO falls from H level to L level. In addition, P channel MOS transistor 3 is rendered conductive, N channel MOS transistor 6 is rendered non-conductive, and node N4 (N11) is held at H level.

When the level of signal VI is then raised from L level to H level, correspondingly, resistance value of N channel MOS transistors 5, 13 decreases, resistance value of P channel MOS transistors 4, 12 increases, and the level of node N4 (N11) lowers from H level to L level. When the level of node N4 (N11) exceeds the threshold potential of NOR gate 22, the level of signal VO rises from L level to H level. In addition, P channel MOS transistor 3 is rendered non-conductive, N channel MOS transistor 6 is rendered conductive, and node N4 (N11) is held at L level.

Next, control signal CNT falls from H level to L level, signal /CNT attains H level, output signal VO of NOR gate 22 attains L level, P channel MOS transistor 3 is rendered conductive, and N channel MOS transistor 6 is rendered non-conductive. Here, output signal VM of NAND gate 1 attains H level, however, a through current does not flow because N channel MOS transistor 7 is non-conductive.

In the second embodiment, N channel MOS transistor 6 is rendered non-conductive in response to control signal CNT having attained L level. Therefore, a through current does not flow from the line of power supply potential VCC to the line of ground potential GND even when control signal CNT falls from H level to L level. Thus, ratio of current driving power of NAND gate 1 to that of N channel MOS transistors 5-7 as well as Schmitt width VIH-VIL can be freely designed. In addition, as the through current does not flow, power consumption will be small.

Obviously, the same effect will be obtained even if positions of P channel MOS transistors 3 and 4 or positions of N channel MOS transistors 5 and 6 are switched.

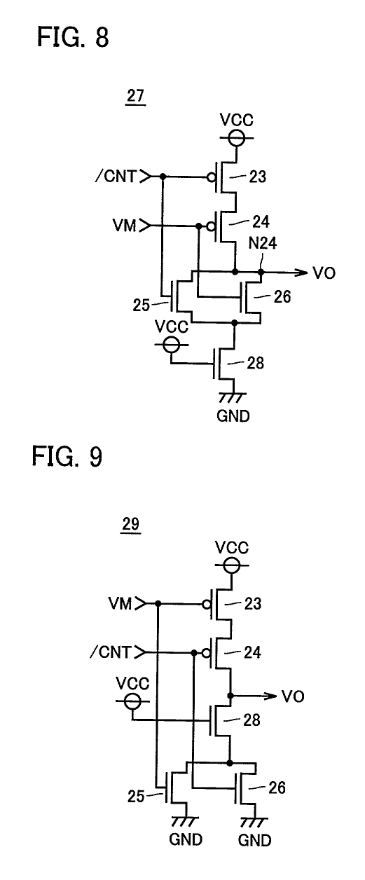

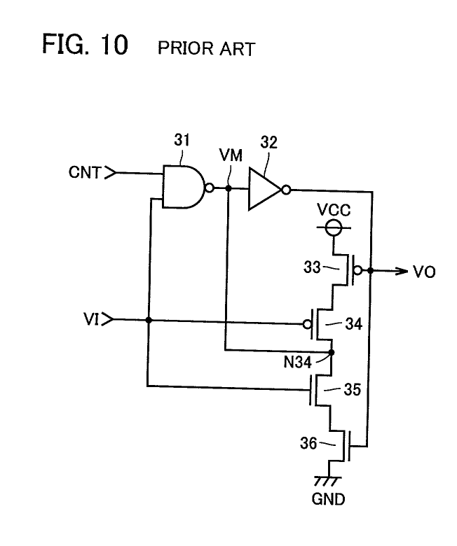

In the following, several variations will be described. In a variation in FIG. 8, NOR gate 22 is replaced with an NOR gate 27. NOR gate 27 is different from NOR gate 22 in FIG. 7 in that an N channel MOS transistor 28 is added. N channel MOS transistor 28 is interposed between sources of N channel MOS transistors 25, 26 and the line of ground potential GND, and receives power supply potential VCC at a gate thereof. N channel MOS transistor 28 constitutes a resistive element. In this variation, two P channel MOS transistors 23, 24 and two N channel MOS transistors 26, 28 constitute an inverter when control signal CNT is at H level. Thus, symmetry of the circuit can be easily obtained.

In a variation in FIG. 9, NOR gate 22 is replaced with an NOR gate 29. In NOR gate 29, positions of N channel MOS transistors 25, 26 and N channel MOS transistor 28 in NOR gate 27 in FIG. 8 are switched. In addition, signal /CNT is provided to gates of MOS transistors 24, 26 and signal VM is provided to gates of MOS transistors 23, 25. Here also, the same effect as in the variation in FIG. 8 will be obtained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A Schmitt trigger circuit setting an output signal to a second potential in response to an input signal having exceeded a first threshold potential when said output signal is at a first potential, and setting said output signal to said first potential in response to said input signal having exceeded a second threshold potential when said output signal is at said second potential, comprising:
a logic circuit outputting an inverted signal of an input signal of said Schmitt trigger circuit to a prescribed node in response to a control signal having attained an active level, and providing said first potential to said prescribed node in response to said control signal having attained an inactive level;
an inverting circuit outputting an inverted signal of a signal appearing at said prescribed node, as an output signal of said Schmitt trigger circuit;
a first transistor of a first conductivity type and a second transistor of a second conductivity type, receiving an input signal of said Schmitt trigger circuit at respective input electrodes;
a switching element rendered non-conductive in response to said control signal having attained the inactive level; and
a switching circuit switching between said first and second threshold potentials by connecting said first transistor between a line of said first potential and said prescribed node in response to an output signal of said inverting circuit set to said second potential and by serially connecting said second transistor and said switching element between a line of said second potential and said prescribed node in response to an output signal of said inverting circuit set to said first potential.

2. The Schmitt trigger circuit according to claim 1, wherein
said switching element includes a third transistor of the second conductivity type;
the Schmitt trigger circuit further comprising a fourth transistor of the first conductivity type receiving at an input electrode said second potential; and wherein
said switching circuit serially connects said first and fourth transistors between the line of said first potential and said prescribed node in response to an output signal of said inverting circuit set to said second potential.

3. The Schmitt trigger circuit according to claim 1, wherein
said logic circuit includes
fifth and sixth transistors of the first conductivity type, connected in parallel between the line of said first potential and said prescribed node, and receiving said control signal and said input signal at respective input electrodes, and
seventh and eighth transistors of the second conductivity type serially connected between the line of said second potential and said prescribed node, one of said transistors receiving at an input electrode said control signal, and the other one of said transistors receiving at an input electrode said input signal.

4. The Schmitt trigger circuit according to claim 3, wherein
said logic circuit further includes a ninth transistor of the first conductivity type, serially connected to each of said fifth and sixth transistors between the line of said first potential and said prescribed node, and receiving at an input electrode said second potential.

5. A Schmitt trigger circuit setting an output signal to a second potential in response to an input signal having exceeded a first threshold potential when said output signal is at a first potential, and setting said output signal to said first potential in response to said input signal having exceeded a second threshold potential when said output signal is at said second potential, comprising:
a first logic circuit outputting an inverted signal of an input signal of said Schmitt trigger circuit to a prescribed node in response to a control signal having attained an active level, and providing said first potential to said prescribed node in response to said control signal having attained an inactive level;
a second logic circuit outputting an inverted signal of a signal appearing at said prescribed node, as an output signal of said Schmitt trigger circuit in response to said control signal having attained an active level, and outputting said second potential in response to said control signal having attained the inactive level;
a first transistor of a first conductivity type and a second transistor of a second conductivity type, receiving at input electrodes an input signal of said Schmitt trigger circuit; and
a switching circuit switching between said first and second threshold potentials by connecting said first transistor between a line of said first potential and said prescribed node in response to an output signal of said second logic circuit set to said second potential and by connecting said second transistor between a line of said second potential and said prescribed node in response to an output signal of said second logic circuit set to said first potential.

6. The Schmitt trigger circuit according to claim 5, wherein
said first logic circuit includes
third and fourth transistors of the first conductivity type, connected in parallel between the line of said first potential and said prescribed node, and receiving said control signal and said input signal at respective input electrodes, and
fifth and sixth transistors of the second conductivity type serially connected between the line of said second potential and said prescribed node, one of said transistors receiving at an input electrode said control signal, and the other one of said transistors receiving at an input electrode said input signal.

7. The Schmitt trigger circuit according to claim 6, wherein
said first logic circuit further includes a seventh transistor of the first conductivity type, serially connected to each of said fifth and sixth transistors between the line of said first potential and said prescribed node, and receiving at an input electrode said second potential.

8. The Schmitt trigger circuit according to claim 5, wherein
said second logic circuit includes
ninth and tenth transistors of the first conductivity type serially connected between the line of said first potential and an output node, one of said transistors receiving at an input electrode an inverted signal of said control circuit, and the other one of said transistors receiving at an input electrode a signal appearing at said prescribed node, and
eleventh and twelfth transistors of the second conductivity type, connected in parallel between the line of said second potential and said output node, and receiving an inverted signal of said control signal and the signal appearing at said prescribed node at respective input electrodes.

9. The Schmitt trigger circuit according to claim 8, wherein
said second logic circuit further includes a thirteenth transistor of the second conductivity type, serially connected to each of said eleventh and twelfth transistors between the line of said second potential and said output node, and receiving at an input electrode said first potential.
